(19) United States
(12) Patent Application Publication
(10) Pub. No.: US 2024/0363413 A1
(43) Pub. Date: Oct. 31, 2024

(54) LASER DICING TO CONTROL SPLASH

(71) Applicant: TEXAS INSTRUMENTS INCORPORATED, DALLAS, TX (US)

(72) Inventors: Bo LIN, CHENGDU (CN); Qing RAN, CHENGDU (CN)

(21) Appl. No.: 18/308,303

(22) Filed: Apr. 27, 2023

(51) Int. Cl. H01L 21/78

(52) U.S. Cl. CPC H01L 21/78; H01L 21/268; H01L 21/6836; H01L 2221/68327

(57) ABSTRACT

One example provides a method that includes directing a laser beam at a first side surface of a semiconductor substrate at an entry point along a respective scribe street thereof. The substrate includes a plurality of dies having circuitry at the first side surface and separated from one another by respective scribe streets. The laser beam is focused within the substrate to form a modified region and a crack extending from the modified region towards at least one of the first and second side surfaces. The modified region is closer to the first side surface than a second side surface that is opposite the first side surface. The method also includes applying tape on the first side surface after directing the laser beam, and backgrinding to reduce a thickness of the substrate from the second side surface and provide a thinned second side surface that intersects an extension of the crack.

### TECHNICAL FIELD

This description relates generally to laser dicing to control splash.

### BACKGROUND

Die preparation is a part of the semiconductor device fabrication process in which a wafer is prepared for integrated circuit (IC) packaging and testing. The process of die preparation generally includes wafer dicing also referred to as singulation or die separation. Prior to wafer dicing, the wafer is mounted on a tape (e.g., dicing tape). A wafer dicing process is used to separate individual die from a wafer of semiconductor, while mounted to the dicing tape. The dicing process can involve scribing and breaking, mechanical sawing or laser cutting. Once a wafer has been diced, the dies usually stay on the dicing tape until they are extracted by die-handling equipment, such as a die bonder or die sorter, later in the packaging process.

### SUMMARY

One example described herein relates to method that includes directing a laser beam at a first side surface of a semiconductor substrate at an entry point along a respective scribe street thereof. The substrate includes a plurality of dies having circuitry at the first side surface and separated from one another by respective scribe streets. The laser beam is focused within the substrate to form a modified region and a crack extending from the modified region towards at least one of the first and second side surfaces. The modified region is closer to the first side surface than a second side surface that is opposite the first side surface. The method also includes applying tape on the first side surface after directing the laser beam, and backgrinding to reduce a thickness of the substrate from the second side surface and provide a thinned second side surface that intersects an extension of the crack.

Another example described herein relates to a method that includes directing a laser beam at a first side surface of a semiconductor substrate at an entry point along a respective scribe street thereof. The substrate includes a plurality of semiconductor die having circuitry at the first side surface and separated from one another by respective scribe streets. The laser beam is focused within the substrate to form a modified region and a crack extending from the modified region in a direction orthogonal to the first side surface. The modified region is closer to the first side surface than an opposite second side surface of the substrate. The method also includes applying pressure at the first side surface of the substrate to extend the crack towards the first side surface. The method also includes backgrinding to reduce a thickness of the substrate from the second side surface and provide a thinned second side surface that intersects an extension of the crack.

Another example described herein relates to a semiconductor device. The semiconductor device includes a semiconductor die including a substrate having a sidewall surface extending between opposing first and second side surfaces. An integrated circuit is in the substrate at a first location closer to the first side surface than to a second side surface. The sidewall surface includes a single region having a modified texture at a second location between the first location and the second side surface, and the second location is closer to the first side surface than to the second side surface.

### BRIEF DESCRIPTION OF THE DRAWINGS

FIG. 1 is a flow diagram depicting an example method of forming a semiconductor apparatus.

FIGS. 2A, 2B, 3, 4, 5 and 6 are cross-sectional views of a semiconductor device at different stages of processing according to the method of FIG. 1.

FIG. 7 is a diagram showing a side view of an example packaged semiconductor device.

FIG. 8 is a photograph showing a side view of a wafer after performing an example stealth laser dicing method.

### DETAILED DESCRIPTION

This description relates generally to semiconductor devices and methods of semiconductor device fabrication.

For example, a method includes performing a single stealth laser dicing pass, such as by directing a laser beam at a first side surface of a semiconductor substrate (e.g., a wafer) at an entry point along a respective scribe street thereof. The substrate includes a plurality of dies distributed across the substrate, in which each die has circuitry (e.g., one or more integrated circuits (IC's)) at the first side surface and is separated from one another by respective scribe streets. The laser beam is focused within the substrate to form a modified region and a crack extending from the modified region towards at least one of the first and second side surfaces (e.g., in a direction orthogonal to the respective side surfaces). The resulting modified region within the substrate is closer to the first side surface (e.g., adjacent the circuitry) than a second side surface that is opposite the first side surface.

After the laser dicing, tape is applied on the first side surface. The tape can be applied with sufficient force on the first side surface while the second side surface is supported (e.g., on a chuck or other support surface) to extend the crack towards the first side surface. For example, a roller or other device is configured to apply pressure onto an exposed surface of tape that has been applied to the first side surface. The tape can be a backgrind tape, and the method thus further includes backgrinding the second side surface to reduce a thickness of the substrate from the second side surface and provide a thinned second side surface. The backgrinding can also cause further extension of the crack towards one or both side surfaces. The backgrinding can be implemented (e.g., by a surface grinder or grinding wheel) to remove a sufficient amount of the substrate material from the second side surface so the thinned second surface intersects a second side-facing extension of the crack.

A dicing tape can be applied to the thinned second side surface, and the backgrind tape can be removed from the first side. The dicing tape can be expanded in the directions of the saw streets to separate (or singulate) the respective die from one another and provide a desired die-to-die gap to facilitate further fabrication. The further fabrication can include packaging each of the dies in a molding material, such as plastic or ceramic. As a further example, the methods described herein provide the sidewall surfaces of each die with a particular modified surface texture region (e.g., silicon damage layer) located between the IC and the thinned second side surface, in which the location of the modified surface texture (e.g., in a Z-direction) is closer to the first side surface than to the thinned second side surface.

As used herein, the term semiconductor device (and its variants) refers to any structure or apparatus that includes a semiconductor substrate. For example, a semiconductor substrate (e.g., a wafer) having a plurality of integrated circuit (IC) dies formed thereon is a semiconductor device. An individual die or group of die, which may be on a wafer or separated from the wafer, is another example of a semiconductor device. Additionally, one or more dies that have been packaged in molding material is yet another example of a semiconductor device. Thus, a semiconductor device can exist at any stage of the semiconductor fabrication workflow including the resulting packaged IC chip or system on chip (SOC).

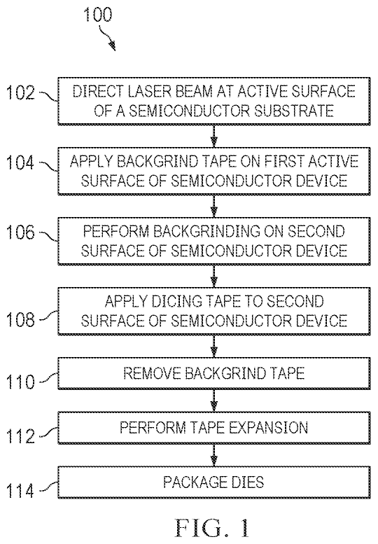

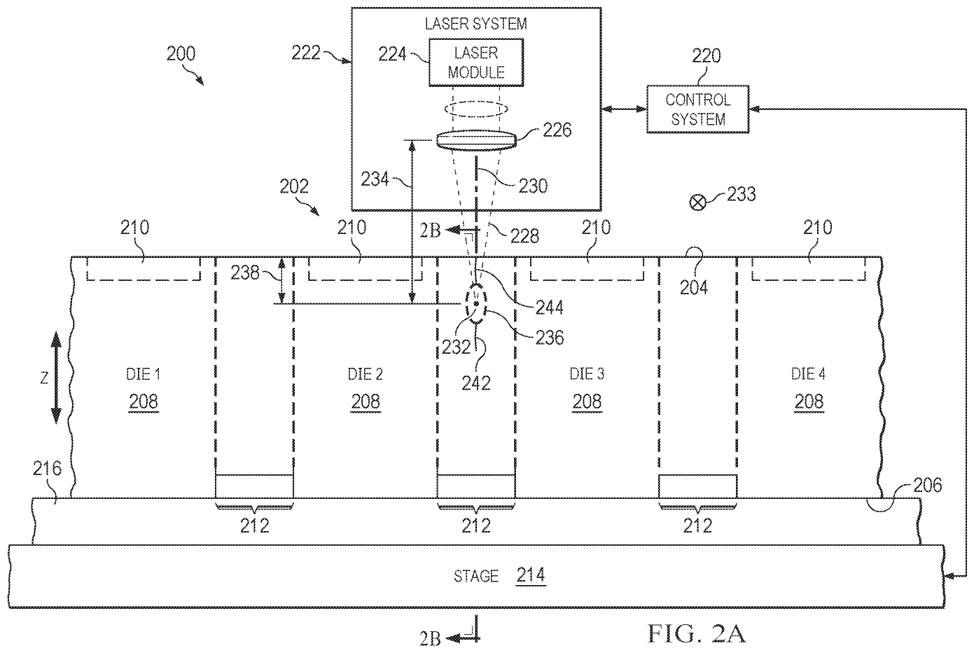

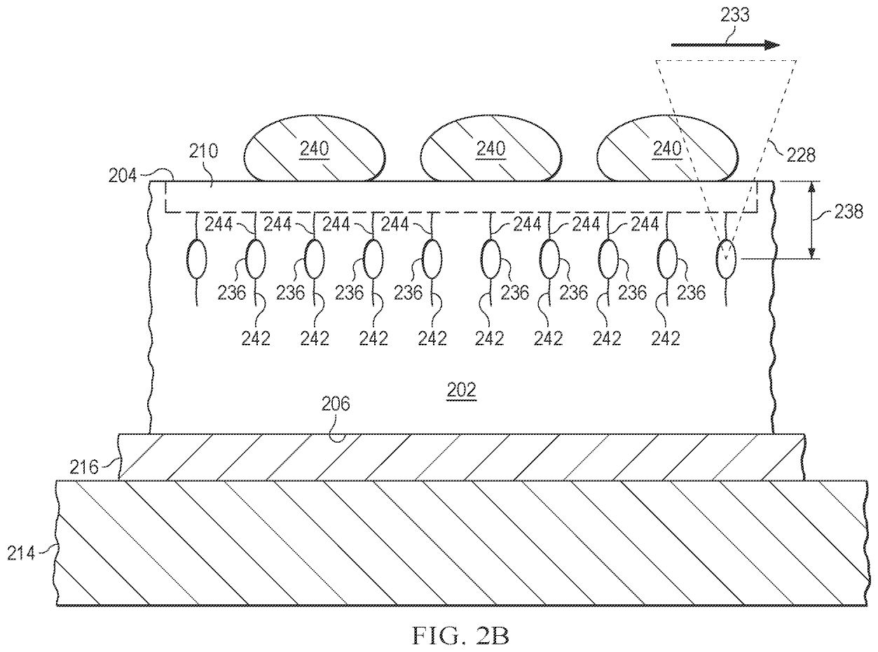

FIG. 1 is a flow diagram depicting an example method 100 that can be implemented to perform die preparation as part of an overall semiconductor fabrication workflow. The method 100 is described in relation to the cross-sectional views of FIGS. 2A, 2B, 3, 4, 5, 6 and 7, which show an example processing progression of wafer preparation that can be used in a semiconductor fabrication workflow to form one or more semiconductor devices from a semiconductor substrate (e.g., also referred to herein as a wafer). The wafer includes first and second opposing side surfaces and a plurality of semiconductor dies distributed across the first side surface and separated from adjacent dies by respective saw streets. Each die includes circuitry formed therein at or near the first side surface. Electrically conductive bumps can also are formed on the first side surface of respective dies to electrically couple input and/or output terminals of the circuitry. The wafer is mounted on a chuck with the active side facing up.

At 102, the method 100 includes performing stealth laser dicing of the substrate by directing a laser beam at the first side (e.g., the active side) surface of the substrate. For example, FIG. 2A shows a laser dicing system 200 configured to implement stealth laser-based dicing of a semiconductor substrate 202. The substrate 202 includes a first and second opposing side surfaces 204 and 206 and a sidewall extending between the side surfaces, which provides the thickness of the wafer along a Z-direction orthogonal to the first and second side surfaces. For example, the first side surface 204 is a top side (also referred to as the front or active side) of the wafer 202 and the second side surface 206 is a bottom side (also referred to as the back side) of the wafer. The wafer 202 has a surface on the second side and includes a plurality of semiconductor die 208, shown as die 1, die 2, die 3, and die 4. Each die 208 has circuitry 210 formed therein at or near the active surface 204. Each of the die 208 are separated from one another by respective scribe streets 212. Thus, respective scribe streets 212 are located between adjacent die 208.

As shown in the example of FIG. 2A, the stage 214 includes chuck 216 (e.g., a vacuum chuck) configured to support the wafer 202 during laser dicing at 102. The system 200 also includes a control system 220 coupled to the stage 214 and to a laser system 222. The control system 220 is configured to control movement of the stage 214 along its several degrees of freedom to position the stage and a wafer 202 supported by the chuck 216 relative to the laser system 222. The control system 220 is also configured to control operation of the laser system 222 to direct an incident laser beam (e.g., a pulsed beam) to perform stealth laser dicing within a given scribe street 212 as the stage 214 is moved along a scan direction parallel to the given scribe street and orthogonal to the incident surface 204 of the wafer 202. For example, the control system 220 controls parameters of the laser system 222 and the stage to perform stealth laser dicing during a single-pass stealth laser dicing process, as described herein. The parameters can include pulse rate (e.g., pulse frequency), pulse pitch, feed speed, split beam distance, stage position and motion, optical wavelength, beam energy level, focal length of the beam, beam width and the like.

As schematically shown in FIG. 2A, the laser system 222 includes a laser module 224. For example, the laser module 224 is configured to generate an infrared (IR) laser beam 228. The laser system 222 also includes an arrangement of optics, such as including one or more focusing lenses 226. The laser module 224 includes a laser light source configured to perform pulsed oscillation of laser light along an optical axis 230 while the lens 226 is adjusted (e.g., by control system 220) to focus beam at a focal point 232 located within the wafer 202 along a respective scribe street 212. The focusing lens 226 may also be referred to as a condensing lens and move in a direction parallel to the optical axis 230, to adjust the position of the focal point of the focused laser beam. The distance between the lens 226 and the focal point 232 defines a focal length 234, which can be set to different distances (by the control system 220). For example, a scan direction of the laser beam 228 is indicated by a symbol shown at 233 (e.g., orthogonal to the planar surface of page on which FIG. 2A is presented—i.e., into the page). The beam 228 moves in the scan direction 233 within a respective scribe street 212, such as by moving the stage 214 linearly beneath the pulsed laser beam while set to a given focal length.

The laser beam 228 is provided at a wavelength capable of transmitting through the wafer 202 and is directed at an entry location (also referred to as an entry point) on the first surface 204 of the wafer 202 within respective scribe streets 212. As an example, the laser module 224 is configured to pulse the laser beam 228 at a frequency of about 50 KHz to 200 kHz, such as 100 kHz, while the stage 214 moves the wafer 202 relative to the laser beam 228 with a velocity (e.g., ranging from about 0.5 m/see to about 2 m/s). The laser beam 228 is scanned (e.g., linearly) across the wafer to stay within the scribe streets 212 to circumscribe each die on the wafer 202 during each pass. As a further example, the laser module 224 includes a pulsed laser (e.g., an Nd: YAG laser) outputting a wavelength of 1,064 nm. The laser module 224 is adapted for silicon dicing applications because the room temperature band gap of silicon is about 1.11 eV (1.12 nm), so that maximum laser absorption can be adjusted by optical focusing. Other types of lasers and wavelengths can be used in other examples depending on the substrate material being used as the wafer 202.

During each pass of the laser through a respective scribe street 212 across the wafer 202, the focused beam 228 is provided with sufficient energy to cause thermal shock at a localized damage zone surrounding the focal point 232. The damage zone can be a volume of substrate material (e.g., silicon), which is referred to herein as a modified region (also referred to as a silicon damage (SD) region). As the pulsed beam 228 is scanned across the wafer, a plurality of adjacent modified regions are formed at a given depth (e.g., depending on the focal length 234 of the beam 228) to provide a respective modified layer (e.g., an SD layer) 236 within the wafer along the length of the scribe street 212. Because the laser dicing at 102 is applied at the first side surface 204 during a single pass there is no incidence of splash onto the circuitry 210, as tends to occur when multiple passes of the laser beam are used.

FIG. 2B is a schematic diagram showing another cross-sectional view of a portion of the substrate 202 taken along lines 2B-2B in FIG. 2A. In the example of FIG. 2B, the substrate includes bumps 240 on the surface 204, which are not shown in the example of FIG. 2A. Also in the example of FIG. 2B, the laser beam 228 is scanned laterally across the surface in the direction 233 to form respective modified regions 236 within the substrate during laser dicing (at 102).

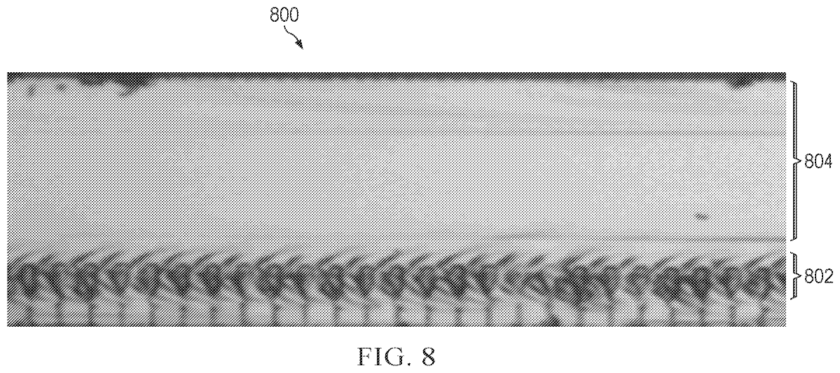

In the example of FIG. 2A, a single modified region 236 is shown, which can be considered to be representative of a respective modified layer that includes a plurality of such modified regions embedded within each of the scribe streets 212 of the wafer 202 during a given pass of the laser beam focused at a certain depth within the wafer. An arrangement of modified regions 236 at a given depth form a modified layer within a scribe street is shown in the example of FIG. 2B. While the modified regions 236 are shown schematically as having circular or ellipsoid shapes, the modified regions typically has more unstructured shapes according to the crystalline structure and interaction between the beam 228 and substrate materials (see, e.g., FIG. 8).

As shown in FIGS. 2A and 2B, a distance 238 between the surface 204 and a center (or centroid) of the modified region 236 is along the Z-direction and thus is also referred to herein as the Z-height. A center of the modified region also can constitute the focal point 232 during lasing. As shown in FIGS. 2A and 2B, the modified region 236 is closer to the first side surface 204 than to the second side surface 206. In an example, the modified region 236 is spaced less than approximately 30 micrometers (e.g., less than 20 micrometers) from the first side surface, which is represented by the Z-height 238. As a result, the circuitry 210 in each die 208 is likewise spaced in the Z-direction between the modified region 236 and the first side surface 204.

As described herein, the laser beam 228 also forms a crack extending from the modified region 236 along the Z-direction, shown as respective crack portions 242 and 244. The crack portion (e.g., a bottom crack) 242 extends from the modified region towards the second side surface 206 to terminate in an end thereof. The other crack portion (e.g., a top crack) 244 extends from the modified region towards the first side surface 204 to terminate in an end thereof. While the crack 242, 244 is depicted to extend straight (e.g., linearly), such cracks typically follow a more non-linear and/or non-uniform path along the Z-direction according to the material structure of the substrate 202.

The length that each crack portion 242 and 244 extends in the Z-direction from the modified regions 236 is controllable based on the laser parameters, including power, frequency, and beam width to name a few. The control system 220 thus can be configured to control the lengths of respective cracks that are formed during laser dicing (at 102), such as to ensure that the cracks 244 do not extend all the way to the first side surface 204 to avoid damaging the circuitry 210. Additionally, the length of each crack 242, 244 also can also be controlled to inhibit breaking the wafer into pieces after laser dicing and during handling in subsequent processing steps before actual die separation. For example, a distance between the top end of the crack 244 and the first side surface 204 (e.g., the active side) of the wafer 202 is less than a distance between a lower edge of the circuitry 210 and the first side surface (e.g., about 10 micrometers). The control system 220 can control the laser parameters differently in other examples to provide different crack lengths and relative placement of cracks with respect to the circuitry 210.

The control system 220 is configured to control the laser module to provide a Z-height for the modified regions 236 and lengths of respective cracks 242 and 244 to inhibit (e.g., prevent) damage to the circuitry 210 and avoid premature separation between adjacent dies 208. For example, the parameters for a given application can vary depending on energy absorption rate of the material of the wafer, for example, depending on the doping density of the wafer. The power, the frequency, beam width and Z-height can be determined empirically, such as by conducting a number of tests.

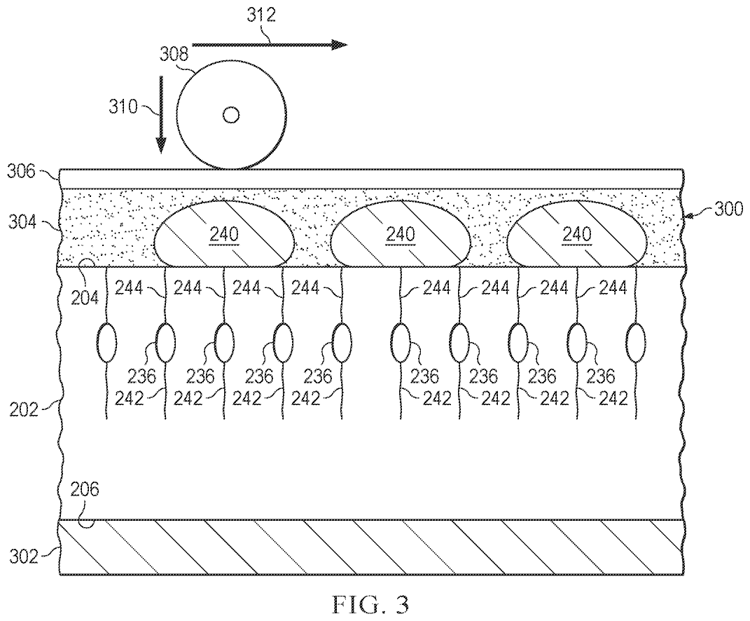

At 104, backgrind tape is applied to the first (e.g., active) side surface of the semiconductor substrate (e.g., a wafer). For example, as shown in FIG. 3, backgrind tape 300 is applied to the first side surface 204 of the wafer 202, which can be supported by a wafer chuck (or other support surface, such as a table), shown at 302. The tape 300 can be an ultraviolet (UV) curable grinding tape that include a substrate layer 306 and one or more adhesive layers (e.g., a UV curable adhesive) 304 to bond temporarily to first side surface 204 of the wafer 202 for subsequent grinding. The adhesive material 304 can be sufficiently pliant and conformable over the bumps 240.

As shown in the example of FIG. 3, a roller 308 is configured to apply pressure (e.g., ranging from about 0.2 mpa to about 0.5 mpa) onto the tape 302 in a direction 310 orthogonal to the surface 204. The applied pressure (or at least a substantial portion thereof) is transferred to the surface 204 to extend the cracks 244 from the modified regions 236 towards the first surface 204. The roller 308 can apply the pressure concurrently with applying the tape 300 (at 104) onto the surface 204 or after applying the tape, such as by moving the roller across the wafer surface 204 in the direction shown at 312. While a roller 308 is shown in the example of FIG. 3, another device (e.g., a tapper apparatus) can be used to apply force onto the first side surface to extend cracks 244 from the modified regions 236. The applied pressure or other force applied to the first side surface 204 can also result in some extension of the cracks 242 towards the second side surface 206. The pressure applied by the roller or another device can be sufficient to cause the cracks 244 to extend from each SD region towards (but not reach) the side surfaces, such that the ends of the respective cracks remain spaced apart from the side surfaces 204 and 206.

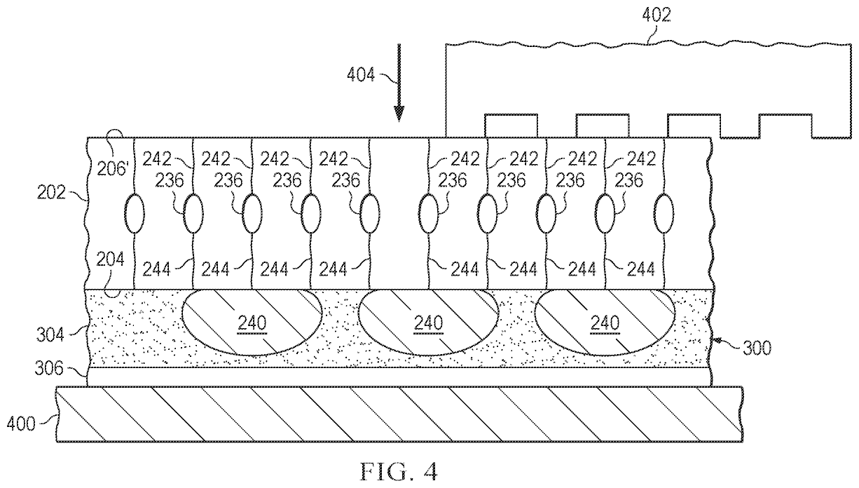

At 106, the method includes performing backgrinding on the second side surface. For example, as shown in FIG. 4, the wafer 202 is mounted on a stage 400 after the tape 300 has been applied (at 104) to the opposite side surface 204. The tape 300 helps to protect the circuitry 210 during the backgrinding at 106, which is performed to thin the second (e.g., back) side 206 of the wafer. FIG. 3 also shows a grinding wheel 402 supported above the stage 400 and configured to thin the substrate by grinding and/or polishing.

In an example, the stage 400 can be moveable in two or more orthogonal directions parallel to the surface of the wafer 202 (e.g., to provide movement in at least two degrees of freedom), such as in five degrees of freedom, such as along three orthogonal axes as well as pitch and roll directions. Alternatively, the stage 400 can be stationary and the grinding wheel 402 can be movable with respect to the wafer 202. The grinding wheel 402 is configured to remove a layer of the substrate from the first side surface to provide a thinned second side surface, shown at 206′.

During grinding, the contact surface of the grinding wheel 402 can be urged onto the side surface 206 being thinned and applies pressure in a direction 404, which is orthogonal to the surface. The applied pressure is sufficient to cause the cracks 242 and 244 to extend further towards adjacent respective side surfaces 206 and 204 of the wafer 202. For example, the backgrinding at 106 can be performed to cause the cracks 244 intersect with (e.g., are exposed at) the first side surface 204 of the wafer. Additionally, the backgrinding can be performed at 106 until the cracks 242 intersect with the thinned second side surface 206′ of the wafer and a desired thickness of the wafer has been reached (e.g., 50 micrometers to 100 micrometers). In an example, the backgrinding implemented at 106 removes at least 40% (e.g., up to approximately 90%) of the thickness of the wafer from the second side surface 206 of the wafer 202. The amount of the material removed during the backgrinding can depend on the desired thickness of the die and the type of package being fabricated.

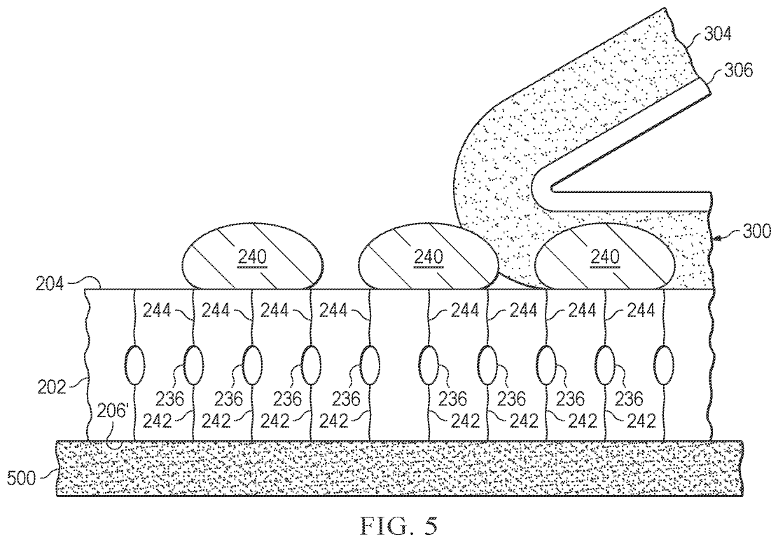

At 108, the method includes applying a dicing tape to the second side surface of the substrate that was thinned at 106. For example, as shown in FIG. 5, dicing tape 500 is applied to the backside surface 206′ opposite the backgrind tape 300. After the dicing tape is applied at 108, the method includes removing the backgrind tape from the first side surface 204, at 110. For example, as also shown in FIG. 5, the backgrind tape is peeled from the surface 204, such as manually or through an automated peeling process.

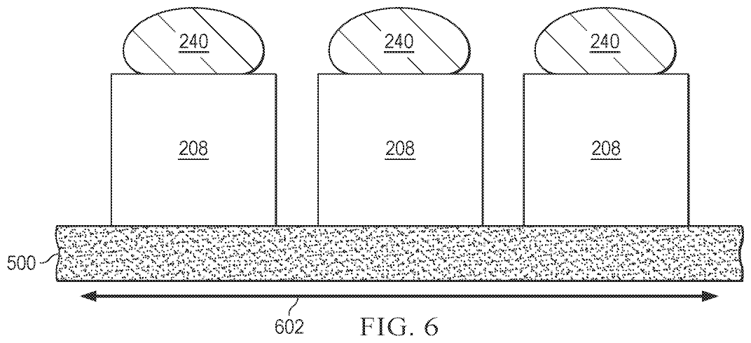

The remaining dicing tape 500 is an integrated tape structure having a backing layer, such as can be made of Polyvinyl chloride (PVC), polyolefin, or polyethylene backing material, and an adhesive to hold the wafer 202 in place during expansion at 112. At 112, tape expansion is performed. For example, as shown in FIG. 6, the tape expansion (at 112) expands wafer to separate the dies along cracks extending through the respective scribe streets to space adjacent die apart from one another by a distance (e.g., a known distance). For example, as shown schematically in FIG. 6, the wafer 202 is expanded uniformly in orthogonal directions (e.g., including as shown by arrow 602 and along another direction—not shown—orthogonal to the arrow 602 (e.g., orthogonal to the surface of the drawings sheet). The directions of expansion thus are parallel to the backside surface and are orthogonal to the directions of the respective scribe streets, such as to space the respective dies apart along the scribe street by a desired die-to-die gap.

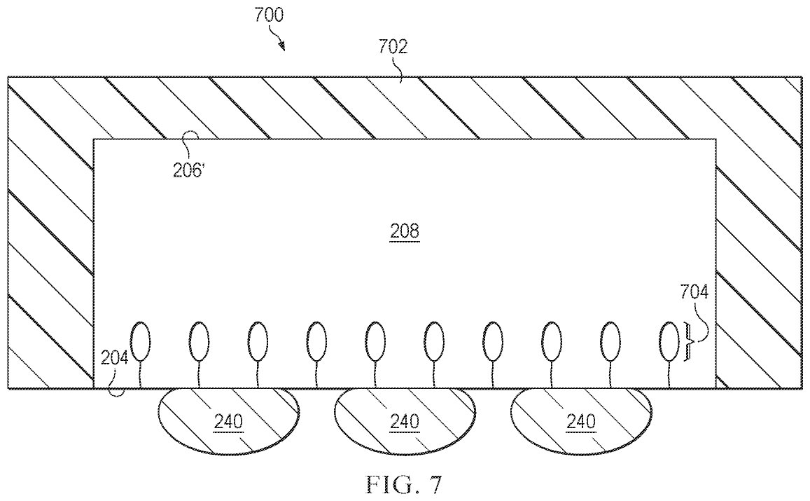

The separated dies can remain on the dicing tape and/or be removed for further processing at 114 to provide one or more packaged semiconductor devices. For example, as shown in FIG. 7, a packaged semiconductor device 700 includes a layer of molding material 702 over the semiconductor die 208. The packaged semiconductor device 700 also includes a single SD layer 704 along the sidewall. The SD layer 704 is closer to the first side surface 204 than to the thinned second side surface 206′. The molding material can be any suitable IC chip packaging material, such as a plastic material or ceramic material, to provide a packaged semiconductor device. The method of FIG. 1 can be used to produce a device according to virtually any packaging technology, including a wafer chip scale package, chip scale package or other package type. One or more bumps 240 can extend from the first side surface 204, such as described herein.

In an example, the separated dies can undergo additional processing prior to packaging at 114. Such further processing can include picking up respective die can be picked from the dicing tape and physically attaching the die to a leadframe using a die attach material (e.g., epoxy attach, eutectic solder attach, or glass frit attach), such as for quad flat no lead (QFN) packages. In some examples, wire bonding can be utilized to connect leads on the die surface to respective terminals of the leadframe. For the example of wafer-level chip-scale packages (WCSP) packages, the WCSP packages can be placed into reels for further testing and distribution. The resulting die assembly can be packaged (e.g., encapsulated) in the molding material to provide the package semiconductor device 700.

The following Table 1 shows examples of test results of performing the method 100 through backgrinding (at 106) for with different process parameters. In Table 1, BHC refers to a backside half cut, in which the half cut along an upper layer of the wafer closer to the first (e.g., active) side surface. BHC “yes” means vertical length of crack is sufficient to extend the thickness of the upper layer near the surface.

TABLE 1

| | Z Height | Laser | | | | Grind |
|---|---|---|---|---|---|---|
| Pass | (Micrometer) | Power | | BHC | BROKEN | result |
| 1pass | 13-18 | 2.0 | W | Yes | No broken | Good |
| | | | | | | separation |
| 1pass | 13-18 | 1.4 | W | Yes | No broken | Good |
| | | | | | | separation |
| 1pass | 13-18 | 1 | W | Yes | No broken | Good |
| | | | | | | separation |

As a further example, Table 2 shows examples of successful test results from performing the method 100 with different process parameters results of whole wafer validation. In Table 2, HC refers to half cut along a lower layer closer to the second side surface of the wafer. HC “no” means the crack not extending to the side opposite to the circuit layer. Also, in Table 2, BQ refers to beam quality, which is a machine parameter of laser beam, and slit refers to width of the laser beam (e.g., 10 refers to a width parameter of the laser system.

TABLE 2

| | | | | Freq. | Z Height | Power | | | | | |
|---|---|---|---|---|---|---|---|---|---|---|---|
| Leg | Pass | Beam | Offset | (kHz) | (μm) | (W) | BQ | Slit | BHC | HC | Separation |
| Leg-4 | 1pass | Single | 2 | 100 | 16 | 1.6 | BQ1 | 10 | Yes | Yes | Yes |

FIG. 8 shows a cross-sectional side view of a wafer 800 after the proposed laser dicing at 102. In the example of FIG. 8, the sidewall of the wafer includes only one SD layer 802 located close to the active side (e.g., first side surface 204) of the wafer. The portion of the sidewall between the SD layer 802 and the opposite surface, shown at 804, is representative of the texture of crack line through the wafer, such as can be separated due to wafer expansion (at 112) from an adjacent sidewall of another die.

In this description, the term “couple” or “couples” means either an indirect or direct connection. Thus, if a first device couples to a second device, that connection may be through a direct connection or through an indirect connection via other devices and connections. For example, if device A generates a signal to control device B to perform an action, then: (a) in a first example, device A is coupled to device B; or (b) in a second example, device A is coupled to device B through intervening component C if intervening component C does not alter the functional relationship between device A and device B, so device B is controlled by device A via the control signal generated by device A.

Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof. Furthermore, a circuit or device described herein as including certain components may instead be configured to couple to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor wafer and/or integrated circuit (IC) package) and may be configured to couple to at least some of the passive elements and/or the sources to form the described structure, either at a time of manufacture or after a time of manufacture, such as by an end user and/or a third party.

The recitation “based on” means “based at least in part on.” Therefore, if X is based on Y, X may be a function of Y and any number of other factors.

Modifications are possible in the described embodiments, and other embodiments are possible, within the scope of the claims.

What is claimed is:

1. A method comprising:
directing a laser beam at a first side surface of a semiconductor substrate at an entry point along a respective scribe street thereof, wherein the substrate includes a plurality of dies having circuitry at the first side surface and separated from one another by respective scribe streets, the laser beam is focused within the substrate to form a modified region and a crack extending from the modified region towards at least one of the first and second side surfaces, and the modified region is closer to the first side surface than a second side surface that is opposite the first side surface;
applying tape on the first side surface after directing the laser beam; and
backgrinding to reduce a thickness of the substrate from the second side surface to provide a thinned second side surface that intersects an extension of the crack.

2. The method of claim 1, wherein:
applying the tape includes sufficient force on the first side surface to extend the crack towards the first side surface, and
backgrinding includes extending the crack towards at least one of the first and second side surfaces.

3. The method of claim 2, wherein applying the tape includes using a roller to press the tape onto the first side surface while supported on the second side surface.

4. The method of claim 1, wherein directing the laser beam includes a single pass of the laser beam along the respective scribe street to provide a respective single silicon damage layer constituting the modified region within the substrate.

5. The method of claim 1, wherein the modified region is spaced less than 20 micrometers from the first side surface.

6. The method of claim 5, wherein the circuitry is spaced between the modified region and the first side surface.

7. The method of claim 1, wherein the tape is a backgrind tape, the method further comprising:
applying a dicing tape to the second side surface of the substrate; and
removing the backgrind tape from the first side surface.

8. The method of claim 7, further comprising performing tape expansion to separate the semiconductor dies from one another.

9. A respective semiconductor die produced according to the method of claim 8, wherein:
the circuitry in the substrate is at a first location closer to the first side surface than to the second side surface,
the respective semiconductor die includes at least one sidewall surface between the first and second side surfaces thereof, the at least one sidewall surface including a single modified texture region at a second location between a first location and the second side surface, in which the second location is closer to the first side surface than to the second side surface.

10. The method of claim 1, wherein directing the laser beam includes controlling the laser beam to have a focal point and beam width based on a location of the circuitry relative to the first side surface and a width of the respective scribe street.

11. A method comprising:
directing a laser beam at a first side surface of a semiconductor substrate at an entry point along a respective scribe street thereof, wherein the substrate includes a plurality of semiconductor die having circuitry at the first side surface and separated from one another by respective scribe streets, the laser beam is focused within the substrate to form a modified region and a crack extending from the modified region in a direction orthogonal to the first side surface, and the modified region is closer to the first side surface than an opposite second side surface of the substrate;
applying pressure at the first side surface of the substrate to extend the crack towards the first side surface; and
backgrinding to reduce a thickness of the substrate from the second side surface and provide a thinned second side surface that intersects an extension of the crack.

12. The method of claim 11, wherein:
applying the pressure includes applying tape onto the first side, and
backgrinding includes extending a first portion of the crack to intersect with the first side surface and extending a second portion of the crack towards the second side surface.

13. The method of claim 12, wherein applying the tape includes using a roller to press the tape onto the first side surface while supported on the second side surface.

14. The method of claim 11, wherein the modified region is spaced less than 20 micrometers from the first side surface, and the circuitry is spaced between the modified region and the first side surface.

15. The method of claim 11, wherein:
directing the laser beam includes a single pass of the laser beam along the respective scribe street to provide a respective single silicon damage layer, constituting the modified region within the substrate, and
the method further comprises:
applying dicing tape to the second side surface of the substrate; and
performing tape expansion with the dicing tape to separate the semiconductor dies from one another.

16. A respective semiconductor die produced according to the method of claim 15, wherein the respective semiconductor die includes at least one sidewall surface extending between the first and second side surfaces thereof, the at least one sidewall surface including a single modified texture region at a location between the circuitry and the second side surface that is closer to the first side surface than the second side surface.

17. The method of claim 11, wherein directing the laser beam includes controlling the laser beam to have a focal point and beam width based on a location of the circuitry relative to the first side surface and a width of the respective scribe street.

18. A semiconductor device, comprising:
a semiconductor die including a substrate having a sidewall surface extending between opposing first and second side surfaces; and
an integrated circuit in the substrate at a first location closer to the first side surface than to a second side surface, in which the sidewall surface includes a single region having a modified texture at a second location between the first location and the second side surface, and the second location is closer to the first side surface than to the second side surface.

19. The semiconductor device of claim 18, wherein the second location is spaced less than 20 micrometers from the first side surface, and the first location is spaced between the second location and first side surface.

20. The semiconductor device of claim 18, wherein the sidewall surface has the modified texture based on separating the semiconductor die from an adjacent die through a modified silicon damage layer of the substrate, and the sidewall surface has a smoother texture outside of the single region based on separating the semiconductor die from the adjacent die through a crack.
